(19) United States
(12) Patent Application Publication
(10) Pub. No.: US 2024/0145389 A1
(43) Pub. Date: May 2, 2024

(54) SEMICONDUCTOR CHIP

(71) Applicant: MEDIATEK INC., Hsinchu City (TW)

(72) Inventors: Li-Chiu WENG, Hsinchu City (TW); Yew Teck TIEO, Hsinchu City (TW); Ming-Hsuan WANG, Hsinchu City (TW); Chia-Cheng CHEN, Hsinchu City (TW); Wei-Yi CHANG, Hsinchu City (TW); Jen-Hang YANG, Hsinchu City (TW); Chien-Hsiung HSU, Hsinchu City (TW)

(21) Appl. No.: 18/361,116

(22) Filed: Jul. 28, 2023

Related U.S. Application Data
(60) Provisional application No. 63/380,965, filed on Oct. 26, 2022.

(51) Int. Cl. H01L 23/528

(52) U.S. Cl. CPC H01L 23/5286

(57) ABSTRACT

A semiconductor chip includes a first intellectual property block. There are a second intellectual property block and a third intellectual property block around the first intellectual property block. There is a multiple metal layer stack over the first intellectual property block, the second intellectual property block, and the third intellectual property block. An interconnect structure is situated in the upper portion of the multiple metal layer stack. The interconnect structure is configured for connecting the first intellectual property block and the second intellectual property block. In addition, at least a part of the interconnect structure extends across and over the third intellectual property block.

### CROSS REFERENCE TO RELATED APPLICATIONS

This application is based on, and claims priority of U.S. Provisional Application No. 63/380,965 filed on Oct. 26, 2022, the entirety of which is incorporated by reference herein.

### BACKGROUND OF THE INVENTION

### Field of the Invention

The present invention relates to a semiconductor chip, and in particular to a semiconductor chip having a short path between two target intellectual property blocks, and the short path extends across and over one or more intellectual property blocks between the target intellectual property blocks.

### Description of the Related Art

The current trend in semiconductor fabrication is for each successive generation of digital electronic apparatuses to be smaller and lighter, and to have improved functionality and better performance, than the previous generation. Several semiconductor chips may be integrated as a larger integrated circuit and packaged into a semiconductor device, such as a 2.5D semiconductor device or a 3D semiconductor device. The contact elements, interposer or redistribution layers are used for connections between the semiconductor chips. Typically, a semiconductor chip includes several intellectual property blocks with different functions, and suitable routing structures are provided to form connection paths for those intellectual property blocks.

In a conventional semiconductor chip, the routing structure for forming a connection path between the target intellectual property blocks needs to be set within the spacing between the target intellectual property blocks. For example, a conventional connection path between intellectual property blocks is situated in the lower level metal layer, and mostly extends along the edges of the intellectual property blocks that are set between the target intellectual property blocks. Thus, in the conventional design, the distance of the connection path between the target intellectual property blocks (such as a DRAM controller and an anti-EMI unit) is long and winding due to the detour. In addition, the larger the semiconductor chip area, the farther the detour.

Although existing semiconductor chip designs have been adequate for their intended purposes, they have not been entirely satisfactory in all respects. For example, a bus with a long length can cause latency issues and poor chip performance. Thus, there are still problems to be overcome with regards to the connection design of the semiconductor chip.

### BRIEF SUMMARY OF THE INVENTION

Some embodiments of the present disclosure provide semiconductor chips. An exemplary embodiment of a semiconductor chip includes a first intellectual property (IP) block. There are a second intellectual property (IP) block and a third intellectual property (IP) block around the first intellectual property (IP) block. There is a multiple metal layer stack over the first intellectual property (IP) block, the second intellectual property (IP) block, and the third intellectual property (IP) block. An interconnect structure is situated in the upper portion of the multiple metal layer stack. The interconnect structure is configured for connecting the first intellectual property (IP) block and the second intellectual property (IP) block. In addition, at least a part of the interconnect structure extends across and over the third intellectual property (IP) block.

In some embodiments, the upper portion of the multiple metal layer stack has a lower resistance than the lower portion of the multiple metal layer stack. In some embodiments, the semiconductor chip further includes a super buffer disposed at the midway of the interconnection between the first IP block and the second IP block. In some embodiments, the super buffer comprises a transmitting cell, an intermediate cell and a receiving cell.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is a top view of an exemplary semiconductor chip, in accordance with some embodiments of the present disclosure.

FIG. 2 is a diagram illustrating an exemplary semiconductor chip with an interconnect structure, in accordance with some embodiments of the present disclosure.

FIG. 3 is a diagram illustrating an exemplary semiconductor chip with super buffers, in accordance with some embodiments of the present disclosure.

FIG. 4A is a diagram illustrating an exemplary transmitting cell, in accordance with some embodiments of the present disclosure.

FIG. 4B is a diagram illustrating an exemplary intermediate cell, in accordance with some embodiments of the present disclosure.

FIG. 4C is a diagram illustrating an exemplary receiving cell, in accordance with some embodiments of the present disclosure.

FIG. 5 is a top view of a portion of the super buffers of a semiconductor chip, in accordance with some embodiments of the present disclosure.

FIG. 6 is an enlarged portion of power/ground signal lines taken from a circled region C1 shown in FIG. 5, in accordance with some embodiments of the present disclosure.

FIG. 7 is an enlarged portion of power/ground signal lines taken from a circled region C2 shown in FIG. 5, in accordance with some embodiments of the present disclosure.

FIG. 8 is a diagram illustrating a portion of a semiconductor chip with an exemplary set of super buffer groups, in accordance with some embodiments of the present disclosure.

FIG. 9 is a top view of a portion of the super buffers of a semiconductor chip, in accordance with some embodiments of the present disclosure.

FIG. 10 is a top view of an enlarging portion of an interconnect structure of the semiconductor chip, in accordance with some embodiments of the present disclosure.

FIG. 11 is a diagram illustrating an exemplary placement of the super buffers of a semiconductor chip, in accordance with some embodiments of the present disclosure.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is determined by reference to the appended claims.

The inventive concept is described fully hereinafter with reference to the accompanying drawings, in which exemplary embodiments of the inventive concept are shown. The advantages and features of the inventive concept and methods of achieving them will be apparent from the following exemplary embodiments that will be described in more detail with reference to the accompanying drawings. It should be noted, however, that the inventive concept is not limited to the following exemplary embodiments, and may be implemented in various forms. Accordingly, the exemplary embodiments are provided only to disclose the inventive concept and let those skilled in the art know the category of the inventive concept. Also, the drawings as illustrated are only schematic and are non-limiting. In the drawings, the size of some of the elements may be exaggerated for illustrative purposes and not drawn to scale. The dimensions and the relative dimensions do not correspond to actual dimensions in the practice of the invention.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It should be understood that when an element is referred to as being “connected” to another element, it may be directly connected to the other element, or intervening elements may be present.

Similarly, it should be understood that when an element such as a layer, region or substrate is referred to as being “on” another element, it can be directly on the other element or intervening elements may be present. In contrast, the term “directly” means that there are no intervening elements. It should be understood that the terms “comprises”, “comprising”, “includes” and/or “including”, when used herein, specify the presence of stated features, integers, steps, operations, elements, and/or components, but do not preclude the presence or addition of one or more other features, integers, steps, operations, elements, components, and/or groups thereof.

Furthermore, spatially relative terms, such as “beneath,” “below,” “lower,” “above,” “upper” and the like, may be used herein for ease of description to describe one element or feature's relationship to another element(s) or feature(s) as illustrated in figures. The spatially relative terms are intended to encompass different orientations of the device in use or operation in addition to the orientation depicted in the figures. It should be understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present invention. Exemplary embodiments of aspects of the present inventive concept explained and illustrated herein include their complementary counterparts. The same or similar reference numerals or reference designators denote the same or similar elements throughout the specification.

Some embodiments of the disclosure are described. It should be noted that additional operations or components can be provided before, during, and/or after the operations or components described in these embodiments. Some of the operations or components that are described can be replaced or eliminated for different embodiments. Additional features can be added to the semiconductor chip. Some of the features described below can be replaced or eliminated for different embodiments. Although some embodiments are discussed with operations performed in a particular order, these operations may be performed in another logical order.

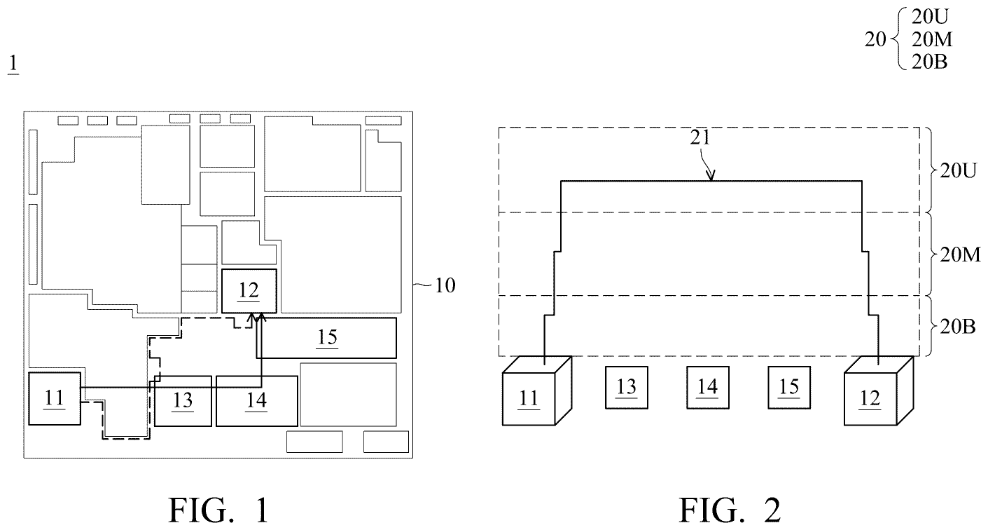

FIG. 1 is a top view of an exemplary semiconductor chip, in accordance with some embodiments of the present disclosure. FIG. 2 is a diagram illustrating an exemplary semiconductor chip with an interconnect structure, in accordance with some embodiments of the present disclosure.

Referring to FIG. 1 and FIG. 2, a semiconductor chip 1 includes several intellectual property (IP) blocks disposed over a substrate 10. In some embodiments, an interconnect structure 21 is formed above the intellectual property (IP) blocks and extends across and over at least one intellectual property (IP) block to connect two of the intellectual property blocks.

In one exemplified embodiments, a semiconductor chip 1 includes a first intellectual property (IP) block 11, a second intellectual property (IP) block 12 and a third intellectual property (IP) block 13 disposed on the substrate 10. The third intellectual property (IP) block 13 is disposed around the first intellectual property (IP) block 11. A multiple metal layer stack 20 of the semiconductor chip is formed at least over the first intellectual property (IP) block 11, the second intellectual property (IP) block 12 and the third intellectual property (IP) block 13. The semiconductor chip 1 further includes an interconnect structure 21 that is situated in an upper portion 20U of the multiple metal layer stack 20. The interconnect structure 21 is configured for connecting the first intellectual property (IP) block 11 and the second intellectual property (IP) block 12. That is, the first intellectual property (IP) block 11 and the second intellectual property (IP) block 12 can be referred to as two target intellectual property (IP) blocks. In some embodiments, at least a part of the interconnect structure 21 extends across and over the third intellectual property (IP) block 13. Therefore, the interconnect structure 21 that flies over another intellectual property (IP) block cuts off the detour between the first intellectual property (IP) block 11 and the second intellectual property (IP) block 12, in accordance with some embodiments of the present disclosure.

In some embodiments, the interconnect structure 21 may extend across and over several intellectual property (IP) blocks in order to connect two target intellectual property (IP) blocks.

Referring to FIG. 1 and FIG. 2 again, in one embodiment, five intellectual property (IP) blocks over a substrate 10 are exemplified for illustrating an electrical connection between two target intellectual property (IP) blocks via an interconnect structure. As shown in FIG. 1 and FIG. 2, a semiconductor chip 1 includes a first intellectual property (IP) block 11, a second intellectual property (IP) block 12, a third intellectual property (IP) block 13, a fourth intellectual property (IP) block 14 and a fifth intellectual property (IP) block 15. The third intellectual property (IP) block 13 is disposed around the first intellectual property (IP) block 11. The fourth intellectual property (IP) block 14 is disposed around the third intellectual property (IP) block 13. The fifth IP block is disposed adjacent to the second IP block 12. A multiple metal layer stack 20 of the semiconductor chip 1 is formed at least over the first intellectual property (IP) block 11, the second intellectual property (IP) block 12, the third intellectual property (IP) block 13, the fourth intellectual property (IP) block 14 and the fifth intellectual property (IP) block 15. The semiconductor chip 1 further includes an interconnect structure 21 that is situated in an upper portion 20U of the multiple metal layer stack 20. The interconnect structure 21 is configured for connecting the first intellectual property (IP) block 11 and the second intellectual property (IP) block 12. The interconnect structure 21 extends across and over at least the third intellectual property (IP) block 13, the fourth intellectual property (IP) block 14 and the fifth intellectual property (IP) block 15.

Two paths for connecting the first intellectual property (IP) block 11 and the second intellectual property (IP) block 12 are also illustrated in FIG. 1. The first intellectual property (IP) block 11 may be, but not limited to, a dynamic random access memory (DRAM) controller, while the second intellectual property (IP) block 12 may be, but not limited to, an anti-electromagnetic interference (anti-EMI) unit for shielding EMI noise. The path P1 (depicted in solid line) represents one of applicable connection paths between the first intellectual property (IP) block 11 and the second intellectual property (IP) block 12, in accordance with some embodiments of the present disclosure. The path P2 (drawn in dotted line) represents a conventional connection path between the first intellectual property (IP) block 11 and the second intellectual property (IP) block 12. Compared with the path P2 that is long and winding due to the detour, the embodied path P1 that flies over the third intellectual property (IP) block 13, the fourth intellectual property (IP) block 14 and the fifth intellectual property (IP) block 15 between the first intellectual property (IP) block 11 and the second intellectual property (IP) block 12 is much shorter. Thus, the embodied path P1 does cut off the detour of the conventional path P1. The bus with a shorter distance between the first intellectual property (IP) block 11 (e.g., DRAM controller) and the second intellectual property (IP) block 12 (e.g., anti-EMI unit) decreases latency issues of the chip performance, in accordance with some embodiments of the present disclosure.

In addition, as shown in FIG. 2, in some embodiments, the multiple metal layer stack 20 includes a bottom portion 20B, a middle portion 20M and an upper portion 20U. The bottom portion 20B is formed over the first to fifth intellectual property (IP) blocks 11-15. The middle portion 20M is formed on the bottom portion 20B. The upper portion 20U is formed on the middle portion 20M. In addition, each of the bottom portion 20B, the middle portion 20M and the upper portion 20U of the multiple metal layer stack 20 may include several level metal layers.

In one example, the bottom portion 20B of the multiple metal layer stack 20 may include the first, second, third and fourth level metal layers, which can be referred to as the metal layers M1, M2, M3 and M4 for abbreviation. The middle portion 20M of the multiple metal layer stack 20 may include the fifth, sixth, seventh, eighth, ninth and tenth level metal layers, which can be referred to as the metal layers M5, M6, M7, M8, M9 and M10. The upper portion 20U of the multiple metal layer stack 20 may include the eleventh and the twelfth metal layers, which can be referred to as the metal layers M11 and M12, and/or another higher level metal layer. The interconnect structure 21 that is situated in the upper portion 20U of the multiple metal layer stack 20 and configured for connecting the first intellectual property (IP) block 11 and the second intellectual property (IP) block 12, as described above, may be formed by using portions of the metal layers M11 and M12, in accordance with some embodiments of the present disclosure.

It should be noted that those metal layers of the multiple metal layer stack 20, such as metal layers M1 to M12 above, are provided for illustrating one applicable design of the multiple metal layer stack 20 over the intellectual property (IP) blocks, in accordance with some embodiments of the present disclosure. The present disclosure is not limited thereto. Therefore, the bottom portion 20B may include two or more metal layers, and it is not limited to four metal layers such as metal layer M1 to metal layer M4 as exemplified above. The middle portion 20M may include five or more metal layers (such as five metal layers, seven metal layers, etc.), and it is not limited to six metal layers such as metal layer M5 to metal layer M10 as exemplified above. The upper portion 20U may include three or more metal layers, and it is not limited to two metal layers such as metal layer M11 and metal layer M12 as exemplified above.

In addition, in some embodiments, the upper portion 20U of the multiple metal layer stack 20 has a lower resistance than a lower portion of the multiple metal layer stack 20. For example, the resistance of the upper portion 20U is lower than the resistance of the middle portion 20M, and is also lower than the resistance of the bottom portion 20B. In some embodiments, the upper portion 20U of the multiple metal layer stack 20 uses one or more low resistance metal layers. For example, the metal layers M11 and M12 (and/or another higher level metal layer) may include gold (Au) wires, silver (Ag) wires, copper (Cu) wires, or the wires made of another suitable material with low resistance. Therefore, the signal transmission speed between the first intellectual property (IP) block 11 and the second intellectual property (IP) block 12 via the interconnect structure 21 that is situated in the lower resistance upper portion 20U can be increased.

In addition, it should be noted that the interconnect structure 21 includes numerous metal wires between the first intellectual property (IP) block 11 and the second intellectual property (IP) block 12, and FIG. 2 merely depicts one of the metal wires of the interconnect structure 21 for exemplification. The wider the metal wire, the lower the resistance. In some embodiments, the width of each of the metal wires of the interconnect structure 21 is greater than the width of one of the metal wires in the middle portion 20M of the multiple metal layer stack 20 to decrease the resistance. In one example, the width of a metal wire of the interconnect structure 21 is at least twice the width of the metal wire in the middle portion 20M of the multiple metal layer stack 20.

To achieve the interconnection between two intellectual property (IP) blocks via an interconnect structure 21 situated in the upper portion 20U of the multiple metal layer stack 20, one or more super buffers may be disposed at the midway of the interconnection between two intellectual property (IP) blocks. In some embodiments, the super buffers are situated in the middle portion 20M of the multiple metal layer stack 20.

FIG. 3 is a diagram illustrating an exemplary semiconductor chip with super buffers, in accordance with some embodiments of the present disclosure. In some embodiments, one or more super buffers are disposed on the route between the first intellectual property (IP) block 11 and the second intellectual property (IP) block 12 to reduce the transition violation.

As shown in FIG. 3, the super buffers 31, 32 and 33 are disposed sequentially at the midway of the interconnection between the first intellectual property (IP) block 11 and the second intellectual property (IP) block 12. The super buffer is configured to drive signal in a long wire in order to ensure the signal integrity, thereby reducing the transition violation. In some embodiments, a super buffer is configured to drive signals in a long wire of about 1500 um to about 3000 um in length. In some embodiments, a total length of the route between two adjacent super buffers (e.g., between the super buffers 31 and 32, or between the super buffers 32 and 33) is less than 3000 um; for example, the total length of the route between two adjacent super buffers is in a range of, but not limited to, about 1500 um to about 2900 um.

Although three super buffers 31, 32 and 33 are provided for illustrating one applicable design of the electrical connection between the first intellectual property (IP) block 11 and the second intellectual property (IP) block 12, the present disclosure is not limited thereto. The number of super buffers disposed at the midway of the interconnection between two target intellectual property (IP) blocks can be determined and varied according to a distance of the interconnect structure 21 that flies over one or more intellectual property (IP) blocks for connecting the target intellectual property (IP) blocks of the semiconductor chip in the application.

The super buffers that are disposed at the midway of the interconnection between two intellectual property (IP) blocks may include three different cell types; that is, a type of transmitting cell, an intermediate cell and a receiving cell. The three different cell types may be built in a super buffer, or each of the cell types may be built in a super buffer, depending on the chip design in the application. In some embodiments, a super buffer includes one transmitting cell, one or more intermediate cells and one receiving cell. Alternatively, in some other embodiments, the super buffer 31 includes a transmitting cell, the super buffer 32 includes an intermediate cell and the super buffer 33 includes a receiving cell.

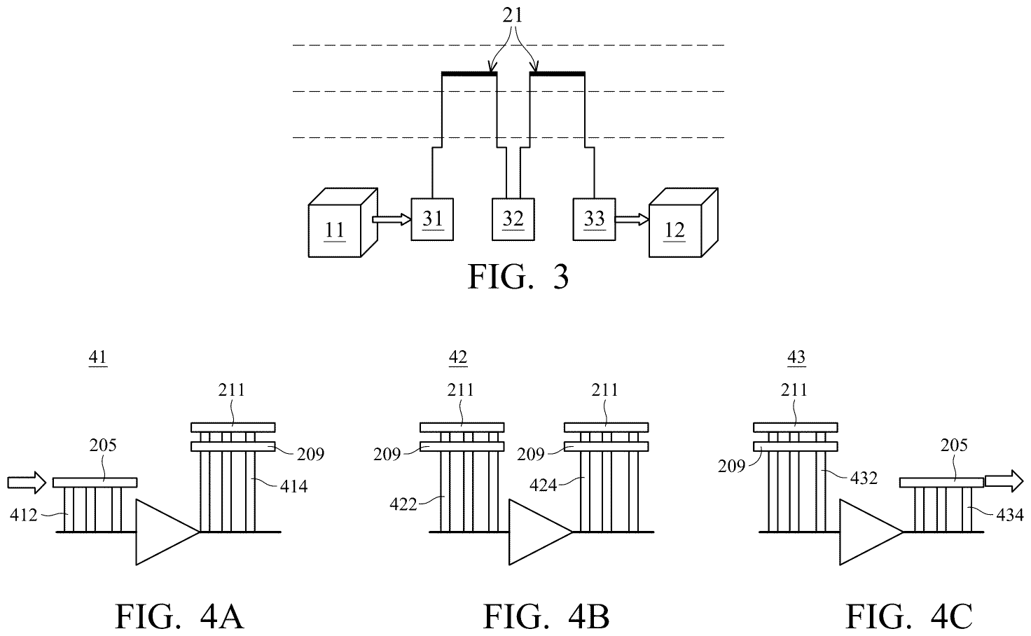

FIG. 4A is a diagram illustrating an exemplary transmitting cell 41, in accordance with some embodiments of the present disclosure. A transmitting cell 41 includes several input pins 412 and several output pins 414. In addition, there is a solid connection between the input pins 412 and a main processing portion (not shown) of the transmitting cell 41. Similarly, there is a solid connection between the output pins 414 and the main processing portion of the transmitting cell 41.

Referring to FIG. 2 and FIG. 4A, in some embodiments, the input pins 412 and the output pins 414 of the transmitting cell 41 are situated in the middle portion 20M of the multiple metal layer stack 20. For example, the input pins 412 are situated at a first conductive layer 205 (such as metal layer M5) of the middle portion 20M of the multiple metal layer stack 20, and the output pins 414 are situated at a second conductive layer 209 (such as metal layer M9) of the middle portion 20M of the multiple metal layer stack 20. The second conductive layer 209 is disposed above the first layer 205 and separated from the first conductive layer 205 by other conductive layers (such as metal layers M6, M7 and M8).

Referring to FIG. 2 and FIG. 4A, the input pins 412 are configured to receive the signals from the first intellectual property (IP) block 11, and the output pins 414 are configured for transmitting signals to the interconnect structure 21. In some embodiments, the output pins 414 are electrically connected to the interconnect structure 21 through suitable interconnect features (such as one or more metal lines and vias between the output pins 414 and the interconnect structure 21). For example, the interconnect structure 21 includes a conductive layer 211 (such as metal layer M11) in the upper portion 20U of the multiple metal layer stack 20. In some embodiments, the conductive layer 211 is formed of a metal material with lower resistance. The output pins 414 of the transmitting cell 41 are electrically connected to the conductive layer 211 of the interconnect structure 21 through another conductive layer (such as metal layer M10) and suitable vias between the adjacent conductive layers (e.g., vias between M10 and M11).

Therefore, the transmitting cell 41 receives signals from the first intellectual property (IP) block 11, and outputs the signals back to the interconnect structure 21. The signals from the first intellectual property (IP) block 11 can be driven by the transmitting cell 41 to travel a portion of the route of the interconnect structure 21 in a long distance (such as about 3000 um).

FIG. 4B is a diagram illustrating an exemplary intermediate cell 42, in accordance with some embodiments of the present disclosure. If the route of the interconnect structure 21 has a long length, one or more intermediate cells 42 may be required to be configured midway between a transmitting cell 41 and a receiving cell (such as a receiving cell 43 described below).

As shown in FIG. 4B, an intermediate cell 42 has several input pins 422 and several output pins 424. In addition, there is a solid connection between the input pins 422 and a main processing portion (not shown) of the intermediate cell 42. Similarly, there is a solid connection between the output pins 424 and the main processing portion of the intermediate cell 42.

Referring to FIG. 2 and FIG. 4B, in some embodiments, the input pins 422 and the output pins 424 of the intermediate cell 42 are situated in the middle portion 20M of the multiple metal layer stack 20. For example, the input pins 422 and the output pins 424 of the intermediate cell 42 are situated at the same metal layer of the middle portion 20M of the multiple metal layer stack 20. Specifically, the input pins 422 are situated at the second conductive layer 209 (such as metal layer M9) of the middle portion 20M of the multiple metal layer stack 20. The second conductive layer 209 is disposed above the first layer 205 and separated from the first conductive layer 205 (FIG. 4A) by other conductive layers (such as metal layers M6, M7 and M8).

Referring to FIG. 2 and FIG. 4B, the input pins 422 are configured to receive the signals that have been driven by the transmitting cell 41, and the output pins 424 are configured for transmitting signals back to the interconnect structure 21. In some embodiments, the output pins 424 are electrically connected to the interconnect structure 21 through suitable interconnect features (such as one or more metal lines and vias between the output pins 424 and the interconnect structure 21). For example, the interconnect structure 21 includes the conductive layer 211 (such as metal layer M11) in the upper portion 20U of the multiple metal layer stack 20. The output pins 424 of the intermediate cell 42 are electrically connected to the conductive layer 211 of the interconnect structure 21 through another conductive layer (such as metal layer M10) and suitable vias between the conductive layers (e.g., vias between M10 and M11).

Therefore, an intermediate cell 42 receives the signals that have been driven by the transmitting cell 41, and outputs the signals back to the interconnect structure 21. Thus, the signals can be driven by the intermediate cell 42 to travel along another portion of the route of the interconnect structure 21 in a long distance (such as about 3000 um), in accordance with some embodiments of the present disclosure.

If a total length of the route of the interconnect structure 21 is long, two or more intermediate cells 42 may be required to implement the connection between the target IP blocks. In one example, two intermediate cells that include a first intermediate cell and a second intermediate cell are disposed at the midway between a transmitting cell 41 and a receiving cell (such as a receiving cell 43 described below). Configuration of the input pins and output pins of each of the intermediate cells is similar to that of the intermediate cell 42 shown in FIG. 4B. The first intermediate cell is situated between the transmitting cell 41 and the second intermediate cell. The second intermediate cell is situated between the first intermediate cell and a receiving cell. In addition, each of the first intermediate cell and the second intermediate cell is built as a solid block of super buffer. The second intermediate cell receives the signals that have been driven by the first intermediate cell, and outputs the signals back to another section of the interconnect structure 21. Thus, the signals can be driven by the second intermediate cell to travel along a further portion of the route of the interconnect structure 21 in a long distance, in accordance with some embodiments of the present disclosure.

FIG. 4C is a diagram illustrating an exemplary receiving cell 43, in accordance with some embodiments of the present disclosure. A receiving cell 43 includes several input pins 432 and several output pins 434. In addition, there is a solid connection between the input pins 432 and a main processing portion (not shown) of the receiving cell 43. Similarly, there is a solid connection between the output pins 434 and the main processing portion of the receiving cell 43.

Referring to FIG. 2 and FIG. 4C, in some embodiments, the input pins 432 and the output pins 434 of the receiving cell 43 are situated in the middle portion 20M of the multiple metal layer stack 20. For example, the input pins 432 are situated at the second conductive layer 209 (such as metal layer M9) of the middle portion 20M of the multiple metal layer stack 20, and the output pins 434 are situated at the first conductive layer 205 (such as metal layer M5) of the middle portion 20M of the multiple metal layer stack 20. The second conductive layer 209 is disposed above the first layer 205 and separated from the first conductive layer 205 by other conductive layers (such as metal layers M6, M7 and M8).

Referring to FIG. 2 and FIG. 4C, in some embodiments, the input pins 432 are configured to receive the signals that have been driven by the intermediate cell 42, and the output pins 434 are configured for transmitting signals to another processing unit (not shown), such as a register. In addition, the processing unit (e.g., register) is coupled the second intellectual property (IP) block 12. In some embodiments, the input pins 432 are electrically connected to the interconnect structure 21 through suitable interconnect features (such as one or more metal lines and vias between the input pins 432 and the interconnect structure 21). For example, the interconnect structure 21 may include a conductive layer 211 (such as metal layer M11) in the upper portion 20U of the multiple metal layer stack 20. The input pins 432 of the receiving cell 43 are electrically connected to the conductive layer 211 of the interconnect structure 21 through another conductive layer (such as metal layer M10) and suitable vias between the adjacent conductive layers (e.g., M10 and M11).

Therefore, the receiving cell 43 receives the signals driven by the intermediate cell 42, and outputs the signals to a processing unit such as a register. The outputs of the processing unit (e.g., register) are linked to the second intellectual property (IP) block 12. Thus, the signals are transmitted to the processing unit (e.g., register) and the second intellectual property (IP) block 12 sequentially.

According to the aforementioned descriptions, the super buffers (including a transmitting cell 41, at least one intermediate cell 42 and a receiving cell 43) are configured to drive signals in the long route of the interconnect structure 21 that is situated in the upper portion 20U of the multiple metal layer stack 20. The transmitting cell 41, the intermediate cell 42 and the receiving cell 43 are situated in the middle portion 20M of the multiple metal layer stack 20, so that the signal transmission can be achieved by the interconnect structure 21 and the super buffers without traveling to the level of the layers in which the intellectual property (IP) blocks are disposed. Therefore, the signals can be efficiently and integrally transmitted from the first intellectual property (IP) block 11 to the second intellectual property (IP) block 12 through the interconnect structure 21 over the other intellectual property (IP) blocks, and the signal transmission is assisted by the super buffers, in accordance with some embodiments of the present disclosure.

In some embodiments, several groups of super buffers are disposed for implementing signal transmission through the interconnect structure 21 that is configured for connecting the first intellectual property (IP) block 11 and the second intellectual property (IP) block 12. Some of the design details of the super buffers are described below for exemplification.

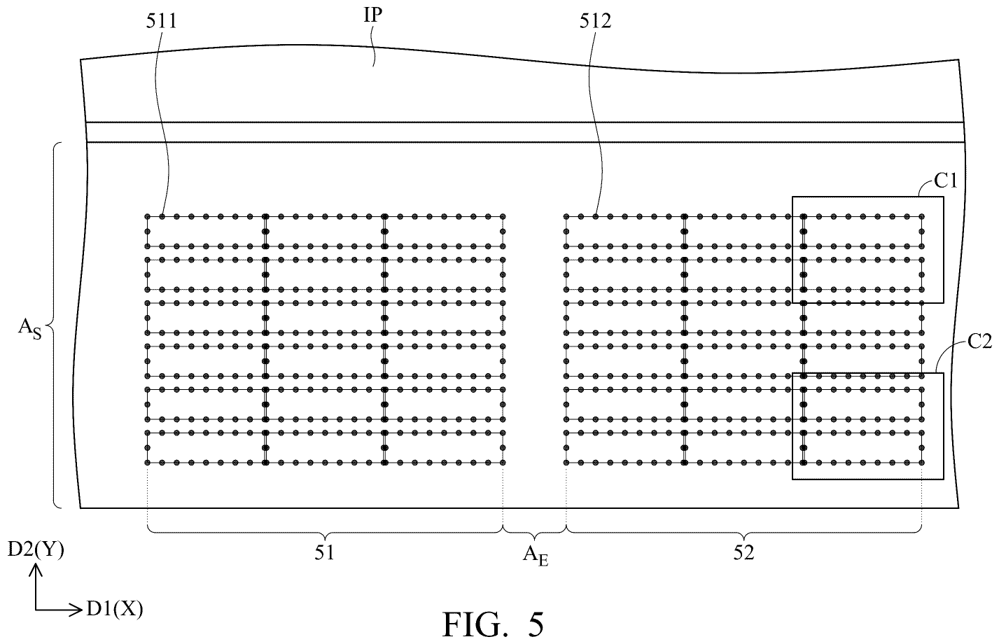

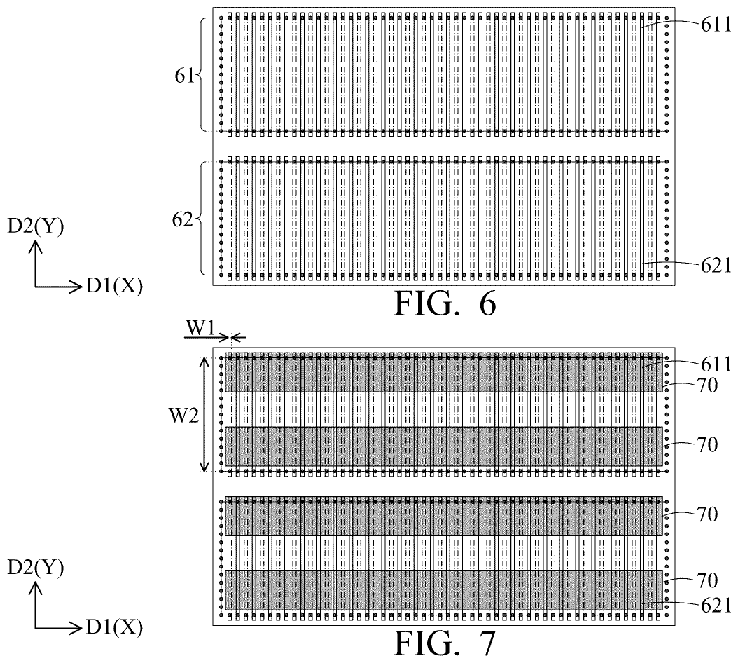

FIG. 5 is a top view of a portion of the super buffers of a semiconductor chip, in accordance with some embodiments of the present disclosure. In some embodiment, several super buffers are disposed in a region A_{S} that is near one of the intellectual property blocks between the first intellectual property block 11 and the second intellectual property block 12. For example, the region A_{S} is near an intellectual property block IP (e.g., the third intellectual property block 13 or another intellectual property block under the interconnect structure 21), and at least a part of the interconnect structure 21 (shown in FIG. 2) extends across and over the intellectual property block IP.

The semiconductor chip may include several groups of super buffers arranged in the first direction D1 (such as the X-direction). For the sake of simplicity and clarity, merely two groups of super buffers are provided in FIG. 5 for exemplification. In this exemplified embodiment, the first group 51 of super buffers includes several super buffers 511 that are lined up with each other. Similarly, the second group 52 of super buffers includes several super buffers 512 that are lined up with each other.

In addition, in some embodiment, it is preferable to leave space between adjacent groups of super buffers for setting the other electrical components to improve the performance of the semiconductor chip. For example, in FIG. 5, the first group 51 of super buffers is separated from the second group 52 of super buffers in the first direction D1 (such as the X-direction) by a region A_{E}. In some embodiments, tap cells can be further added in the regions A_{E} (and also another region between adjacent groups of super buffers). The tap cells are configured to have function of preventing the undesirable latch-up of integrated circuits in the semiconductor chip.

FIG. 6 is an enlarged portion of power/ground signal lines taken from the circled region C1 shown in FIG. 5, in accordance with some embodiments of the present disclosure. As shown in FIG. 6, the first row 61 of power/ground signal lines includes several power/ground signal lines 611 arranged in parallel in the first direction D1 (such as the X-direction) and extend in the second direction D2 (such as the Y-direction). The second row 62 of power/ground signal lines includes several power/ground signal lines 621 arranged in parallel in the first direction D1 and extend in the second direction D2. In some embodiments, the power/ground signal lines 611 of the first row 61 are aligned with the power/ground signal lines 621 of the second row 62. In addition, the power/ground signal lines 611 and 621 are situated in the middle portion 20M of the multiple metal layer stack 20. For example, the power/ground signal lines 611 and 621 are configured in the level of metal layer M9.

Typically, a potential transformer (PT) is an instrument transformer which is used for the protection and measurement purposes in the power systems. The potential transformer (PT) may also be defined as an instrument transformer used for the transformation of voltage from a higher value to the lower value. In some embodiments, adjacent rows of the power/ground signal lines can be connected to each other. In addition, the edges of the super buffers are aligned with the power/ground signal lines (e.g., configured in the level of metal layer M9) that are situated beneath the upper portion 20U (e.g., including metal layers M11 and M12) of the multiple metal layer stack 20. Accordingly, the potential transformer (PT) connection can be improved; for example, the insulation resistance (IR) test of the potential transformer (PT) has better result by aligning and connecting the power/ground signal lines 611 and 621.

FIG. 7 is an enlarged portion of power/ground signal lines taken from the circled region C2 shown in FIG. 5, in accordance with some embodiments of the present disclosure. In some embodiments, at least an extra level of metal layer is required for placing between and connecting the super buffers and the interconnect structure 21 (FIG. 2). For example, the metal layer 70 that is situated in the middle portion 20M of the multiple metal layer stack 20 is configured for connecting the wires of the interconnect structure 21 and the pins of the receiving cell, the intermediate cell(s) and the transmitting cell of the super buffers.

Specifically, in one exemplified embodiment, the power/ground signal lines 611 and 621 are configured in the level of metal layer M9, and the pins of the cells of the super buffers are also situated in the level of metal layer M9. For example, referring to FIG. 4A, FIG. 4B and FIG. 4C, the output pins 414 of the transmitting cell 41, the input pins 422 and the output pins 424 of the intermediate cell 42 and the input pins 432 of the receiving cell 43 are situated in metal layer M9. Since the power/ground signal lines 611/621 and the cell pins that are configured in metal layer M9 are much thinner compared with the wires of interconnect structure 21 (e.g., configured in the level of metal layer M11 or M12; not shown in FIG. 7), the wide metal layer 70 is required for being disposed between metal layer M9 and the interconnect structure 21 to facilitate the connection between the super buffers and the interconnect structure 21, thereby achieving better result of reduced signal electromigration (EM).

In some embodiments, the metal layer 70 that is over the power/ground signal lines 611 and 621 and the pins of the cells of the super buffers can be configured in the level of metal layer M10. As shown in FIG. 7, the power/ground signal lines 611/621 and the cell pins arrangement extend in the second direction D2 (such as the Y-direction), and the metal layer 70 extends continuously in the first direction D1 (such as the X-direction). In addition, in some embodiments, the width W2 (in the second direction D2) of the metal layer 70 is greater than the width W1 (in the first direction D1) of each of the power/ground signal lines 611/621.

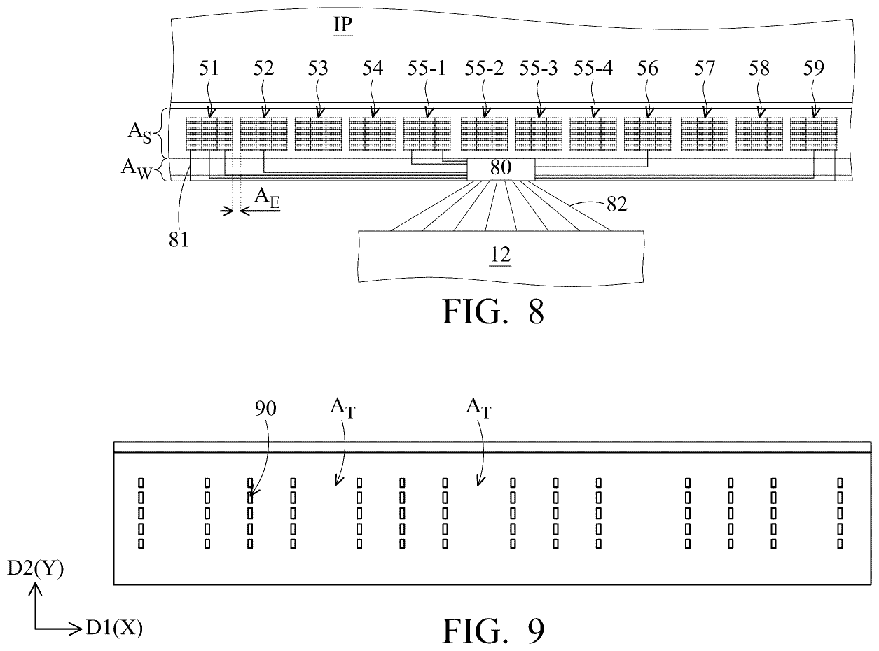

FIG. 8 is a diagram illustrating a portion of a semiconductor chip with an exemplary set of super buffer groups, in accordance with some embodiments of the present disclosure.

In FIG. 8, it exemplifies a set of groups of super buffers, including the groups of super buffers 51 to 54, 55-1 to 55-4 and 56 to 59, is disposed in a region A_{S} near an intellectual property IP. Referring to FIG. 8 and FIG. 2, the intellectual property IP in FIG. 8 may be the third intellectual property block 13 or another intellectual property block that is below the interconnect structure 21 in FIG. 2, wherein at least a part of the interconnect structure 21 extends across and over the intellectual property block IP.

In addition, in some embodiments, a processing unit such as a register 80 is disposed in a region A_{W} that is adjacent to the region A_{S}. That is, the register 80 is positioned between the super buffers and the second intellectual property block 12. In one example, a semiconductor chip includes several super buffers disposed at the midway of interconnection between the first intellectual property block 11 and the second intellectual property block 12. Several super buffers for each wire of the interconnect structure 21 may include a super buffer having a transmitting cell, one or more super buffers having intermediate cells, and another super buffer having a receiving cell. FIG. 8 illustrates the super buffers closest to the register 80.

In some embodiments, the register 80 is disposed around the second intellectual property block 12 to which the signals/data are transmitted from the first intellectual property block 11 (FIG. 2). The register 80 is configured for connecting the receiving cells of the super buffers (such as the groups of super buffers 51 to 54, 55-1 to 55-4 and 56 to 59) and the second intellectual property block 12. As shown in FIG. 8, several bus lines (such as some exemplified bus lines 81) connect the super buffers to the register 80, and the other bus lines (such as some exemplified bus lines 82) connect the register 80 and the second intellectual property block 12. Thus, in some embodiments, the signals from the first intellectual property block 11 can be transmitted to the register 80 through the interconnect structure 21, and then transmitted to the second intellectual property (IP) block 12 by the bus lines 82.

In addition, as shown in FIG. 8, the bus lines 81 are arranged in the region A_{W} to achieve the connection between the super buffers (such as the groups of super buffers 51 to 54, 55-1 to 55-4 and 56 to 59) and the register 80, in accordance with some embodiments of the present disclosure. Therefore, it is preferably to leave enough space in the region A_{W} for arranging the bus lines 81 between the super buffers and the register 80 during implementation of super buffer routing.

In addition, in some embodiments, the register 80 in the region A_{W} can be arranged in middle on bus lines (such as some exemplified bus lines 81) that connect the set of the groups of super buffers to the register 80. For example, the groups of super buffers 55-1 to 55-4 are arranged in a middle portion of the groups of super buffers 51 to 54, 55-1 to 55-4 and 56 to 59, the register 80 can be disposed adjacent to the super buffers 55-2 and 55-3 for balancing the super buffer routing.

FIG. 9 is a top view of a portion of the super buffers of a semiconductor chip, in accordance with some embodiments of the present disclosure. The small blocks in FIG. 9 represent the super buffers 90 that include receiving cells. Since the signal received by the receiving cell is transmitted to a processing unit (such as a register) and not been driven for another long route of the interconnect structure 21, the super buffers 90 that include receiving cells can be formed in a small size for decreasing the power consumption. In some embodiments, the size of the super buffer 90 having the receiving cell can be less than the size of the super buffer having the transmitting cell, and also less than the size of the super buffer having the intermediate cell.

In addition, the super buffers 90 that include receiving cells can be arranged in a regular order; for example, arranged as an array of matrix. Although the super buffers 90 are smaller than the other super buffers that include different types of the cells, it is preferable to leave space between adjacent lines of the super buffers 90 for setting the other electrical components (such as antenna diodes) in order to improve the performance of the semiconductor chip. In some embodiments, the super buffers 90 are lined up in the second direction D2 (such as the Y-direction). Adjacent lines of the super buffers 90 are separated from each other in the first direction D1 (such as the X-direction) by a region A_{T}. Antenna diodes (not shown) can be disposed in the regions A_{T} to address the antenna effect, thereby preventing antenna violation of the semiconductor chip.

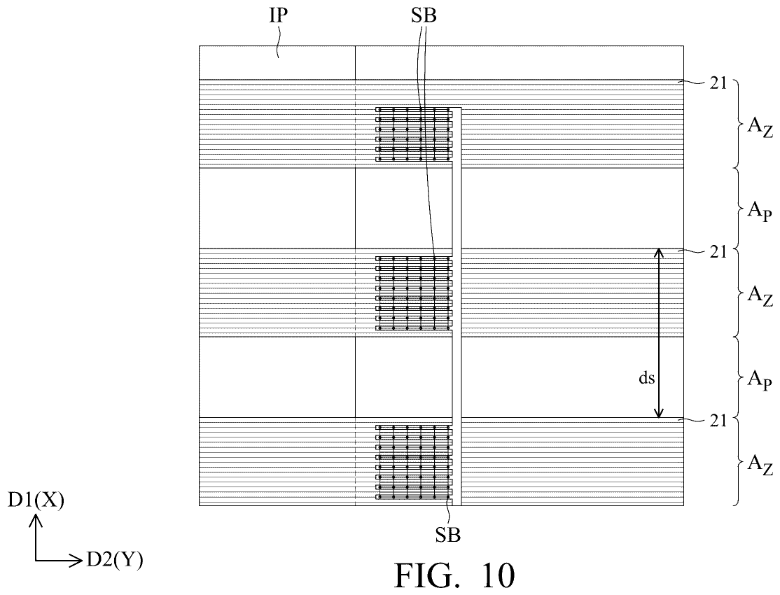

FIG. 10 is a top view of an enlarging portion of an interconnect structure of the semiconductor chip, in accordance with some embodiments of the present disclosure.

In a semiconductor chip, numerous wires are built for connecting an intellectual property block. For example, an anti-EMI block may have about two hundreds of connection wires in the application, and a DRAM controller block may have about three hundreds of connection wires in the application. Even an electromagnetic band gap (EBG) block has more than twenty of connection wires in the application. According to some embodiments, the interconnect structure 21 that is situated in the upper portion 20U of the multiple metal layer stack 20 takes up only portions of the wires in an upper metal layer. Remaining portions of the wires in the upper metal layer are left for building the power/ground routing structures that supply power to the intellectual property blocks of the semiconductor chip.

In this exemplified embodiment, as shown in FIG. 10, the interconnect structure 21 takes up portions of the wires in the z-th level metal layer (which can be referred to as metal layer Mz for abbreviation), and the wires of the e interconnect structure 21 extend in each of the regions A_{Z}. A power/ground routing structure (not shown) that is situated in the upper portion of the multiple metal layer stack takes up the remaining portions of the wires (not shown) in the metal layer Mz, wherein the wires extend in each of the regions A_{P}. The regions A_{Z} and the regions A_{P} are alternately arranged. The interconnect structure 21 in the regions A_{Z} is separated from the power/ground routing structure in the regions A_{P}. In addition, the wires in the metal layer Mz are formed of one or more low resistance metal materials. One super buffer SB is disposed at the midway of each of the wires in the region A_{Z} of the metal layer Mz. For the sake of simplicity and clarity of the drawing, the power/ground routing structure in the regions A_{P} is not shown in FIG. 10.

In one example, a required width of the interconnect structure 21 in a low resistance metal layer (e.g., metal layer Mz) based on 18 nets/set is provided below for exemplification. An EMI net with single side shielding ground-signal-signal-ground (G-S-S-G) pattern (18 nets/set) is shown in FIG. 10. In the regions A_{Z}, the width of the wire in the metal layer Mz and the spacing between the wires are about 0.36 um and 0.36 um, respectively. A spacing ds between adjacent sets of nets is about 36.72 um. The total width of the metal layer Mz is equal to: x/18*36.72 um, wherein x is number of nets.

It should be noted that those numerical values are provided for exemplification, not for limitation. For example, the number for nets/set can be changed (e.g., can be 16 nets/set, 32 nets/set, . . . etc.), and the spacing ds between adjacent sets of nets can be varied, depending on design requirements of the application.

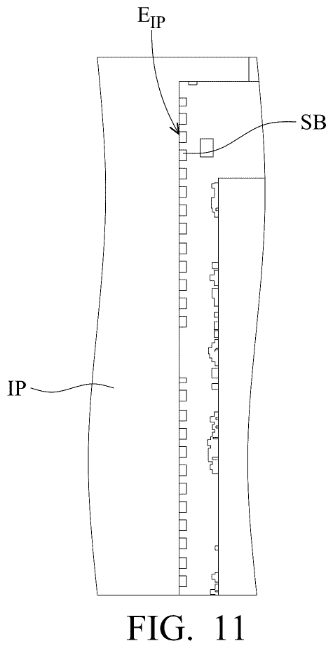

FIG. 11 is a diagram illustrating an exemplary placement of the super buffers of a semiconductor chip, in accordance with some embodiments of the present disclosure.

In some embodiments, the input pins/output pins and the main processing portion of each super buffer SB form a solid connection. Therefore, the super buffers SB can be referred to as a route blockage, and the placement of the super buffers SB should avoid undesired connection. In some embodiments, the super buffers SB are disposed near an edge E_{IP} of an intellectual property IP, such as the third intellectual property block 13 or another intellectual property block below the interconnect structure 21, wherein at least a part of the interconnect structure 21 (shown in FIG. 2) extends across and over the intellectual property block IP.

According to some embodiments described above, the semiconductor chip has several advantages. In some embodiments, a semiconductor chip includes two target intellectual property blocks (such as the first intellectual property block 11 (e.g., DRAM controller) and the second intellectual property block 12 (e.g., anti-EMI unit) as described above) and one or more intellectual property blocks (such as the third intellectual property block 13) between the target intellectual property blocks. The semiconductor chip further includes a multiple metal layer stack over those intellectual property blocks and an interconnect structure that is situated in an upper portion of the multiple metal layer stack. The interconnect structure is configured for connecting two target intellectual property blocks. According to the embodiments, the semiconductor chip has a short path between two target intellectual property (IP) blocks by forming the interconnect structure across cover one or more intellectual property blocks between the two target intellectual property blocks. In addition, in some embodiments, the upper portion of the multiple metal layer stack uses one or more low resistance metal layers, thereby increasing the speed of signal transmission by the interconnect structure. In addition, in some embodiments, one or more super buffers can be disposed at the midway of the interconnect structure between the two target intellectual property blocks to facilitate signal transmission in a long distance of the interconnect structure. Compared with a connection path between the target intellectual property blocks in a conventional semiconductor chip, which is long and winding due to the detour, the target intellectual property blocks of an embodied semiconductor chip has a connection path that flies over one of more intellectual property blocks between the target intellectual property blocks. Thus, the connection path provided in the embodiments is much shorter and do cut off the detour. The shorter buses between two target intellectual property blocks decrease latency issues of the chip performance, in accordance with some embodiments of the present disclosure. Thus, the electrical performance of the semiconductor chip in the embodiments can be greatly improved. Especially when the size of the semiconductor chip is increased, the connection path in the embodiments provides a much more efficient way for connecting the target intellectual property blocks.

It should be noted that the details of the structures of the embodiments are provided for exemplification, and the described details of the embodiments are not intended to limit the present disclosure. It should be noted that not all embodiments of the invention are shown. Modifications and variations can be made without departing from the spirit of the disclosure to meet the requirements of the practical applications. Thus, there may be other embodiments of the present disclosure which are not specifically illustrated. Furthermore, the accompanying drawings are simplified for clear illustrations of the embodiment. Sizes and proportions in the drawings may not be directly proportional to actual products. Thus, the specification and the drawings are to be regard as an illustrative sense rather than a restrictive sense.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor chip, comprising:
a first intellectual property (IP) block;
a second IP block and a third IP block around the first IP block;
a multiple metal layer stack over the first IP block, the second IP block and the third IP block; and
an interconnect structure, situated in an upper portion of the multiple metal layer stack, configured for connecting the first IP block and the second IP block, wherein at least a part of the interconnect structure extends across and over the third IP block.

2. The semiconductor chip according to claim 4, wherein the upper portion of the multiple metal layer stack has a lower resistance than a lower portion of the multiple metal layer stack.

3. The semiconductor chip according to claim 2, further comprising a super buffer disposed on a midway of the interconnection between the first IP block and the second IP block.

4. The semiconductor chip according to claim 3, wherein the super buffer comprises a transmitting cell, an intermediate cell and a receiving cell.

5. The semiconductor chip according to claim 4, wherein an input pin and an output pin of each of the transmitting cell, the intermediate cell and the receiving cell are situated in a middle portion of the multiple metal layer stack, wherein the middle portion is under the upper portion.

6. The semiconductor chip according to claim 5, wherein a metal layer is over the transmitting cell, the intermediate cell and the receiving cell, and is configured for connecting the interconnect structure and the input pins and the output pins of the receiving cell, the intermediate cell and the transmitting cell.

7. The semiconductor chip according to claim 2, wherein the metal layer is configured for connecting power/ground signal lines that are situated in the middle portion of the multiple metal layer stack and arranged in parallel.

8. The semiconductor chip according to claim 7, wherein the metal layer extends continuously over the power/ground signal lines, and a width of the metal layer is greater than a width of each of the power/ground signal lines.

9. The semiconductor chip according to claim 5, wherein the input pin and the output pin of the intermediate cell are situated at the same metal layer of the middle portion of the multiple metal layer stack.

10. The semiconductor chip according to claim 5, wherein the input pin and the output pin of the transmitting cell are respectively situated at a first conductive layer and a second conductive layer of the middle portion of the multiple metal layer stack, and the second conductive layer is above the first conductive layer and separated from the first conductive layer by other conductive layers.

11. The semiconductor chip according to claim 3, wherein the input pin and the output pin of the receiving cell are respectively situated at the second conductive layer and the first conductive layer.

12. The semiconductor chip according to claim 3, further comprising a register between the super buffer and the second IP block, wherein the register is configured for connecting a receiving cell of the super buffer and the second IP block.

13. The semiconductor chip according to claim 3, wherein an edge of the super buffer is aligned with a power/ground signal line that is situated beneath the upper portion of the multiple metal layer stack.

14. The semiconductor chip according to claim 3, wherein the super buffer is disposed near an edge of the third IP block.

15. The semiconductor chip according to claim 1, further comprising a plurality of super buffers disposed on a midway of the interconnection between the first IP block and the second IP block.

16. The semiconductor chip according to claim 15, wherein the plurality of super buffers comprise a first super buffer, a second super buffer and a third super buffer, wherein the first super buffer includes a transmitting cell, the second super buffer includes an intermediate cell, and the third super buffer includes a receiving cell.

17. The semiconductor chip according to claim 16, wherein the third super buffer is smaller than the first super buffer and further smaller than the second super buffer.

18. The semiconductor chip according to claim 16, wherein the plurality of super buffers further comprises:
a fourth super buffer that includes another intermediate cell,
wherein the fourth super buffer is situated at a midway between the second super buffer and the third super buffer.

19. The semiconductor chip according to claim 3, wherein the interconnect structure comprises a plurality of metal wires arranged in parallel, and a width of each of the plurality of the metal wires of the interconnect structure is greater than twice a width of a metal wire in a middle portion of the multiple metal layer stack.

20. The semiconductor chip according to claim 1, further comprising:
a power/ground routing structure, situated in the upper portion of the multiple metal layer stack and separated from the interconnect structure,
wherein the power/ground routing structure supplies power to the first IP block, the second IP block and the third IP block.
